(19) United States
(12) Patent Application Publication
(10) Pub. No.: US 2026/0101688 A1
(43) Pub. Date: Apr. 9, 2026

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: KOKUSAI ELECTRIC CORPORATION, Tokyo (JP)

(72) Inventors: Kimihiko NAKATANI, Toyama (JP); Shoma MIYATA, Toyama (JP); Keitaro HAMADA, Toyama (JP)

(73) Assignee: KOKUSAI ELECTRIC CORPORATION, Tokyo (JP)

(21) Appl. No.: 19/330,913

(22) Filed: Sep. 17, 2025

(30) Foreign Application Priority Data
Oct. 3, 2024 (JP) 2024-174046

(51) Int. Cl. H01L 21/322; H01L 21/02; H01L 21/67

(52) U.S. Cl. CPC H10P 36/00; H10P 14/6334; H10P 72/0408

(57) ABSTRACT

A technique includes (a) preparing a substrate including a first region, which forms an outer surface of a recess and is adjacent to an opening of the recess and whose surface is terminated by a first termination, and a second region, which forms an inner surface of the recess and whose surface is terminated by the first termination; and (b) removing the first termination in the first region by exposing the substrate to a first processing solution containing a liquid that reacts with the first termination, so that a density of the first termination in the first region is smaller than a density of the first termination in the second region.

### CROSS-REFERENCE TO RELATED APPLICATION

This application is based upon and claims the benefit of priority from Japanese Patent Application No. 2024-174046, filed on Oct. 3, 2024, the entire contents of which are incorporated herein by reference.

### TECHNICAL FIELD

The present disclosure relates to a method of processing a substrate, a method of manufacturing a semiconductor device, a recording medium, and a substrate processing apparatus.

### BACKGROUND

In the related art, as a process of manufacturing a semiconductor device, a substrate with a recess formed on its surface may be subjected to a predetermined process.

### SUMMARY

Some embodiments of the present disclosure provide a technique capable of performing a selective processing on a desired region on a surface of a recess formed in a substrate.

According to embodiments of the present disclosure, there is provided a technique that includes (a) preparing a substrate including a first region, which forms an outer surface of a recess and is adjacent to an opening of the recess and whose surface is terminated by a first termination, and a second region, which forms an inner surface of the recess and whose surface is terminated by the first termination; and (b) removing the first termination in the first region by exposing the substrate to a first processing solution containing a liquid that reacts with the first termination, so that a density of the first termination in the first region is smaller than a density of the first termination in the second region.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a substrate processing apparatus suitably used in each embodiment of the present disclosure.

FIG. 2 is a schematic configuration diagram of a vertical process furnace of a film-forming apparatus included in a substrate processing apparatus suitably used in each embodiment of the present disclosure, illustrating a portion of the process furnace in a vertical cross-sectional view.

FIG. 3 is a schematic configuration diagram of the vertical process furnace of the film-forming apparatus included in the substrate processing apparatus suitably used in each embodiment of the present disclosure, illustrating a portion of the process furnace in a cross-sectional view taken along line A-A in FIG. 2.

FIG. 4 is a schematic configuration diagram of a first cleaning apparatus and a second cleaning apparatus included in the substrate processing apparatus suitably used in each embodiment of the present disclosure.

FIG. 5 is a schematic configuration diagram of a controller of the substrate processing apparatus suitably used in each embodiment of the present disclosure, illustrating a control system of the controller in a block diagram.

FIG. 6 is a diagram illustrating regions of inner and outer surfaces of a recess provided on a surface of a wafer in each embodiment of the present disclosure.

FIGS. 7A to 7D are schematic cross-sectional diagrams showing a surface portion of a wafer with a recess in a first embodiment of the present disclosure. FIG. 7A is a partial schematic diagram of the wafer after step a0 is performed. FIG. 7B is a partial schematic diagram of the wafer after step a1 is performed from the state of FIG. 7A. FIG. 7C is a partial schematic diagram of the wafer after step B is performed from the state of FIG. 7B. FIG. 7D is a partial schematic diagram of the wafer after step C is performed from the state of FIG. 7C.

FIGS. 8A to 8D are schematic cross-sectional diagrams showing a surface portion of a wafer with a recess in modification 1 of the first embodiment of the present disclosure. FIG. 8A is a partial schematic diagram of the wafer after step a0 is performed. FIG. 8B is a partial schematic diagram of the wafer after step a1 is performed from the state of FIG. 8A. FIG. 8C is a partial schematic diagram of the wafer after step B is performed from the state of FIG. 8B. FIG. 8D is a partial schematic diagram of the wafer after step C is performed from the state of FIG. 8C.

FIG. 9A to FIG. 9F are schematic cross-sectional diagrams showing a surface portion of a wafer with a recess in a second embodiment of the present disclosure. FIG. 9A is a partial schematic diagram of the wafer after step a0 is performed. FIG. 9B is a partial schematic diagram of the wafer after step a1 is performed from the state of FIG. 9A. FIG. 9C is a partial schematic diagram of the wafer after step B is performed from the state of FIG. 9B. FIG. 9D is a partial schematic diagram of the wafer after step D is performed from the state of FIG. 9C. FIG. 9E is a partial schematic diagram of the wafer after step E is performed from the state of FIG. 9D. FIG. 9F is a partial schematic diagram of the wafer after step F is performed from the state of FIG. 9E.

FIGS. 10A to 10F are schematic cross-sectional diagrams showing a surface portion of a wafer with a recess in modification 1 of the second embodiment of the present disclosure. FIG. 10A is a partial schematic diagram of the wafer after step a0 is performed. FIG. 10B is a partial schematic diagram of the wafer after step a1 is performed from the state of FIG. 10A. FIG. 10C is a partial schematic diagram of the wafer after step B is performed from the state of FIG. 10B. FIG. 10D is a partial schematic diagram of the wafer after step D is performed from the state of FIG. 10C. FIG. 10E is a partial schematic diagram of the wafer after step E is performed from the state of FIG. 10D. FIG. 10F is a partial schematic diagram of the wafer after step F is performed from the state of FIG. 10E.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### First Embodiment of the Present Disclosure

The first embodiment of the present disclosure is described below with reference to the drawings. Drawings used in the following description are schematic, and dimensional relationships of respective elements, proportions of respective elements, and the like shown in the drawings may not match the actual ones. In addition, the dimensional relationships of respective elements, the proportions of respective elements, and the like may not match among multiple drawings.

### (1) Configuration of Substrate Processing Apparatus 100

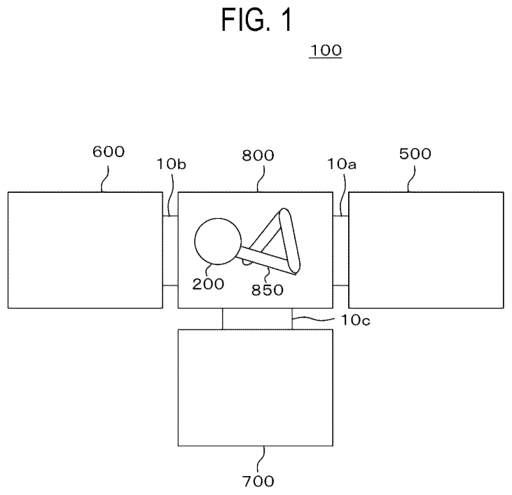

As shown in FIG. 1, the substrate processing apparatus 100 mainly includes a film-forming apparatus 500, a first cleaning apparatus 600, a second cleaning apparatus 700, and a transfer chamber 800.

The film-forming apparatus 500 is an apparatus that performs a film-forming process on a wafer 200 in a substrate processing process described below. The first cleaning apparatus 600 and the second cleaning apparatus 700 are apparatuses that perform a cleaning process on the wafer 200 in the substrate processing process described below. The transfer chamber 800 is a region where the wafer 200 is transferred between the film-forming apparatus 500 and the first cleaning apparatus 600, or between the film-forming apparatus 500 and the second cleaning apparatus 700.

### (i) Configuration of Film-Forming Apparatus 500

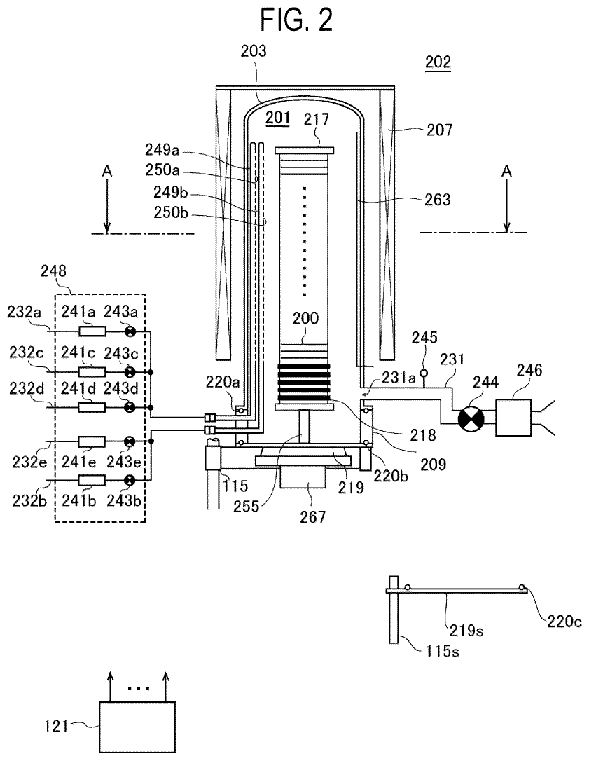

As shown in FIG. 2, a process furnace 202 includes a heater 207 as a temperature regulator (heating part). The heater 207 is formed in a cylindrical shape and is vertically installed by being supported by a holding plate. The heater 207 also functions as an activator (exciter) that activates (excites) a gas with heat.

A reaction tube 203 is disposed concentrically with the heater 207 inside the heater 207. The reaction tube 203 is formed in a cylindrical shape with a closed upper end and an open lower end. A manifold 209 is disposed concentrically with the reaction tube 203 below the reaction tube 203. An O-ring 220a is installed as a seal between the manifold 209 and the reaction tube 203. A process container (reaction container) mainly includes the reaction tube 203 and the manifold 209. A process chamber 201 is formed in a cylindrical hollow portion of the process container. The process chamber 201 is configured to be capable of accommodating wafers 200 as substrates. Processing of the wafers 200 is performed in the process chamber 201.

Nozzles 249a and 249b as a first supplier and a second supplier are installed in the process chamber 201 so as to penetrate a side wall of the manifold 209. The nozzles 249a and 249b are also referred to as a first nozzle and a second nozzle, respectively. Each of the nozzles 249a and 249b is configured as a shared nozzle used to supply multiple types of gas.

Gas supply pipes 232a and 232b as a first pipe and a second pipe are connected to the nozzles 249a and 249b, respectively. Each of the gas supply pipes 232a and 232b is configured as a shared pipe used to supply multiple types of gas. Mass flow controllers (MFCs) 241a and 241b as flow rate controllers (flow rate control parts) and valves 243a and 243b as opening/closing valves are respectively installed at the gas supply pipes 232a and 232b sequentially from an upstream of a gas flow. Gas supply pipes 232c and 232d are connected to the gas supply pipe 232a on a downstream of the valve 243a. MFCs 241c and 241d and valves 243c and 243d are respectively installed at the gas supply pipes 232c and 232d sequentially from an upstream of a gas flow. A gas supply pipe 232e is connected to the gas supply pipe 232b on a downstream of the valve 243b. A MFC 241e and a valve 243e are installed at the gas supply pipe 232e sequentially from an upstream of a gas flow.

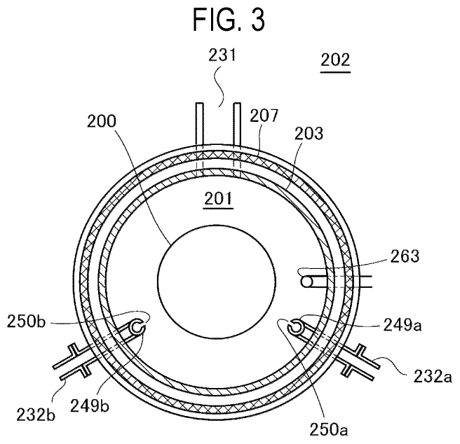

As shown in FIG. 3, the nozzles 249a and 249b are installed in a space between an inner wall of the reaction tube 203 and the wafers 200 so as to extend upward in an arrangement direction of the wafers 200 from a lower portion to an upper portion of the inner wall of the reaction tube 203. In other words, the nozzles 249a and 249b are respectively installed in a region horizontally surrounding a wafer arrangement region, in which the wafers 200 are arranged, on a lateral side of the wafer arrangement region so as to extend along the wafer arrangement region. Gas supply holes 250a and 250b for supplying gases are formed on side surfaces of the nozzles 249a and 249b, respectively. The gas supply holes 250a and 250b are respectively opened so as to face centers of the wafers 200 in a plane view and are capable of supplying gases toward the wafers 200. The gas supply holes 250a and 250b are formed in multiple numbers from a lower portion to an upper portion of the reaction tube 203.

A precursor as a film-forming agent is supplied from the gas supply pipe 232a into the process chamber 201 via the MFC 241a, the valve 243a, and the nozzle 249a.

An oxidizing agent as a film-forming agent is supplied from the gas supply pipe 232b into the process chamber 201 via the MFC 241b, the valve 243b, and the nozzle 249b. The oxidizing agent is one of reactants serving as a film-forming agent.

At least one selected from the group of a first modifying agent and a second modifying agent is supplied from the gas supply pipe 232c into the process chamber 201 via the MFC 241c, the valve 243c, and the nozzle 249a.

An inert gas is supplied from the gas supply pipes 232d and 232e into the process chamber 201 via the MFCs 241d and 241e, the valves 243d and 243e, the gas supply pipes 232a and 232b, and the nozzles 249a and 249b, respectively. The inert gas acts as a purge gas, a carrier gas, a dilution gas, or the like.

A precursor supply system (which may also be referred to as a precursor exposure system) mainly includes the gas supply pipe 232a, the MFC 241a, and the valve 243a. An oxidizing agent supply system or a reactant supply system (which may also be referred to as an oxidizing agent exposure system or a reactant exposure system, respectively) mainly includes the gas supply pipe 232b, the MFC 241b, and the valve 243b. A modifying agent (first and second modifying agents) supply system (which may also be referred to as a modifying agent exposure system) mainly includes the gas supply pipe 232c, the MFC 241c, and the valve 243c. An inert gas supply system mainly includes the gas supply pipes 232d and 232e, the MFCs 241d and 241e, and the valves 243d and 243e. The precursor supply system and the oxidizing agent supply system are also collectively referred to as a film-forming agent supply system (which may also be referred to as a film-forming agent exposure system). Each of the various supply systems described above may include a nozzle connected to a gas supply pipe.

An exhaust port 231a for exhausting an atmosphere in the process chamber 201 is provided at a lower portion of a side wall of the reaction tube 203. An exhaust pipe 231 is connected to the exhaust port 231a. A vacuum pump 246 as a vacuum exhauster is connected to the exhaust pipe 231 via a pressure sensor 245 serving as a pressure detector (pressure detection part) for detecting a pressure inside the process chamber 201 and an APC (Auto Pressure Controller) valve 244 as a pressure regulator (pressure regulation part). The APC valve 244 is configured so that it is capable of performing or stopping vacuum exhaust of an interior of the process chamber 201 by being opened and closed in a state in which the vacuum pump 246 is operated. Further, the APC valve 244 is configured so that it is capable of regulating the pressure inside the process chamber 201 by adjusting a valve opening degree based on pressure information detected by the pressure sensor 245 in a state in which the vacuum pump 246 is operated. An exhaust system mainly includes the exhaust pipe 231, the APC valve 244 and the pressure sensor 245. The vacuum pump 246 may be included in the exhaust system.

A seal cap 219 as a furnace opening lid capable of airtightly closing an opening at a lower end of the manifold 209 is installed below the manifold 209. On an upper surface of the seal cap 219, there is installed an O-ring 220b serving as a seal which abuts against the lower end of the manifold 209. Below the seal cap 219, there is installed a rotator 267 for rotating a boat 217 to be described later. A rotary shaft 255 of the rotator 267 is connected to the boat 217. The rotator 267 is configured to rotate the wafers 200 by rotating the boat 217. The boat elevator 115 as a lift is configured as a transfer device (transferrer) that loads or unloads (transfers) the wafers 200 into and out of the process chamber 201 by raising or lowering the seal cap 219.

A shutter 219s serving as a furnace opening lid capable of air-tightly closing the opening at the lower end of the manifold 209 in a state in which the boat 217 is unloaded from the process chamber 201 is installed below the manifold 209. An O-ring 220c serving as a seal that abuts against the lower end of the manifold 209 is installed on an upper surface of the shutter 219s. Opening/closing operations of the shutter 219s are controlled by a shutter opening/closing mechanism 115s.

A boat 217 as a substrate support is configured so as to support a plurality of wafers 200, for example, 25 to 200 wafers 200 in such a state that the wafers are arranged in a horizontal posture and in multiple stages along a vertical direction with centers of the wafers 200 aligned with one another, i.e., so as to arrange the wafers 200 at intervals. Heat insulating plates 218 are supported in multiple stages at a lower portion of the boat 217.

Inside the reaction tube 203, there is installed a temperature sensor 263 as a temperature detector. By regulating a state of supply of electric power to the heater 207 based on temperature information detected by the temperature sensor 263, a temperature inside the process chamber 201 becomes a desired temperature distribution. The temperature sensor 263 is installed along the inner wall of the reaction tube 203.

### (ii) Configuration of First Cleaning Apparatus 600

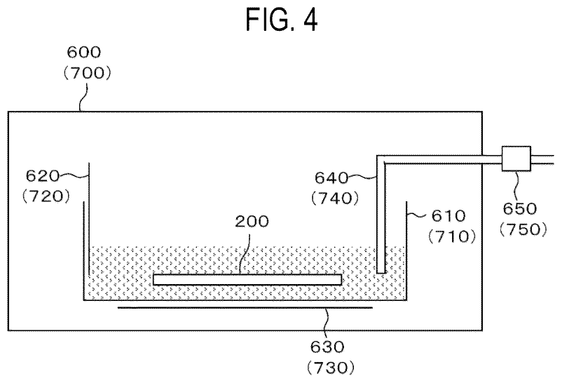

As shown in FIG. 4, the first cleaning apparatus 600 includes a process tank 610. The process tank 610 is capable of accommodating one or more wafers 200. A processing solution supply pipe 640 is connected to a processing solution tank (not shown) via a liquid mass flow controller (LMFC) 650, and is configured to be capable of supplying a processing solution into the process tank 610. The process tank 610 stores the processing solution for exposure, and the wafers 200 are immersed in the processing solution. The processing solution supply pipe 640 and the LMFC 650 constitute a processing solution exposure system (which may also be called a processing solution supply system that supplies the processing solution to the wafers 200) that exposes the wafers 200 to the processing solution. The processing solution exposure system may further include the process tank 610. The first cleaning apparatus 600 includes a temperature sensor 620 that detects a temperature of the processing solution and a heater 630 that regulates the temperature of the processing solution. The temperature sensor 620 is installed along an inner wall of the process tank 610. The heater 630 is disposed in the vicinity of the process tank 610, and is configured to keep the temperature of the processing solution in the process tank 610 at an appropriate temperature based on the temperature sensor 620.

(iii) Configuration of Second Cleaning Apparatus 700

As shown in FIG. 4, the second cleaning apparatus 700 includes a process tank 710. The process tank 710 is capable of accommodating one or more wafers 200. A processing solution supply pipe 740 is connected to a processing solution tank (not shown) via a LMFC 750, and is configured to be capable of supplying a processing solution into the process tank 710. The process tank 710 stores the processing solution for exposure, and the wafers 200 are immersed in the processing solution. The processing solution supply pipe 740 and the LMFC 750 constitute a processing solution exposure system (processing solution supply system) that exposes the wafers 200 to the processing solution. The processing solution exposure system may further include the process tank 710. The second cleaning apparatus 700 includes a temperature sensor 720 that detects a temperature of the processing solution and a heater 730 that regulates the temperature of the processing solution. The temperature sensor 720 is installed along an inner wall of the process tank 710. The heater 730 is disposed in the vicinity of the process tank 710 and is configured to keep the temperature of the processing solution in the process tank 710 at an appropriate temperature based on the temperature sensor 720.

### (iv) Configuration of Transfer Chamber 800

As shown in FIG. 1, the transfer chamber 800 is installed between the film-forming apparatus 500 and the first cleaning apparatus 600, between the film-forming apparatus 500 and the second cleaning apparatus 700, and between the first cleaning apparatus 600 and the second cleaning apparatus 700, via gate valves 10a to 10c. A transferrer 850 for transferring the wafers 200 is installed in the transfer chamber 800. The transferrer 850 places the wafer 200 on a substrate stage installed on an arm and transfers the wafer 200 between the film-forming apparatus 500 and the first cleaning apparatus 600, or between the film-forming apparatus 500 and the second cleaning apparatus 700.

### (v) Controller

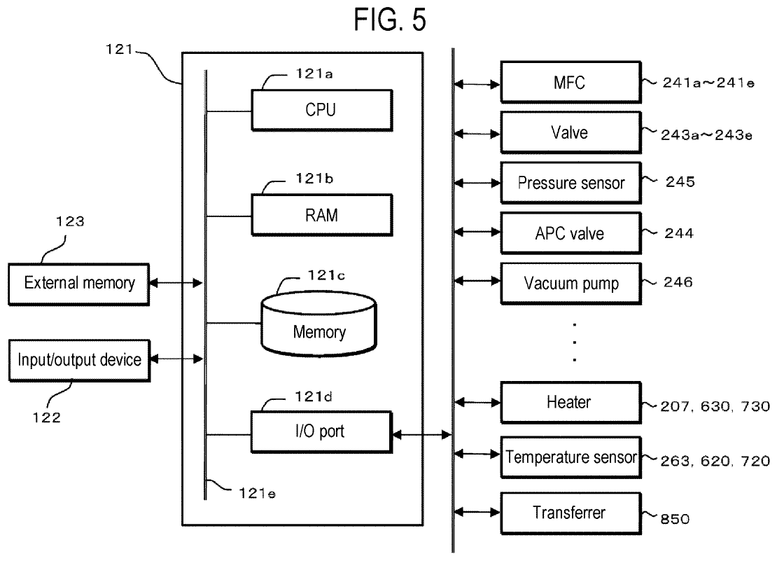

As shown in FIG. 5, the controller 121 as a control part (control means) for the film-forming apparatus 500, the first cleaning apparatus 600, the second cleaning apparatus 700 and the transfer chamber 800 is configured as a computer including a CPU (Central Processing Unit) 121a, a RAM (Random Access Memory) 121b, a memory 121c and an I/O port 121d. The RAM 121b, the memory 121c and the I/O port 121d are configured to be capable of exchanging data with the CPU 121a via an internal bus 121e. An input/output device 122 configured as, for example, a touch panel or the like is connected to the controller 121. Further, an external memory 123 may be connected to the controller 121. The substrate processing apparatus 100 may be configured to include one controller, or may be configured to include a plurality of controllers. That is, the control for performing a processing sequence described below may be performed using one controller, or may be performed using a plurality of controllers. Further, the plurality of controllers may be configured as a control system connected to each other via a wired or wireless communication network, and the control for performing the processing sequence described below may be performed by the entire control system. When the term “controller” is used in the present disclosure, it may include one controller, a plurality of controllers, or a control system configured by a plurality of controllers.

The memory 121c is composed of, for example, a flash memory, a HDD (Hard Disk Drive), a SSD (Solid State Drive), or the like. In the memory 121c, there are readably recorded and stored a control program for controlling an operation of the substrate processing apparatus 100, a process recipe in which procedures and conditions of substrate processing to be described later are written, and the like. The process recipe is a combination that causes the controller 121 to execute respective procedures for the below-described substrate processing in the substrate processing apparatus 100 so as to obtain a predetermined result. The process recipe functions as a program. Hereinafter, the process recipe, the control program, and the like are collectively and simply referred to as a program (program product). Further, the process recipe is also simply referred to as a recipe. When the term “program” is used herein, it may mean a case of solely including the recipe, a case of solely including the control program, or a case of including both the recipe and the control program. The RAM 121b is configured as a memory area in which programs, data and the like read by the CPU 121a are temporarily held.

The I/O port 121d is connected to the MFCs 241a to 241e, the valves 243a to 243e, the pressure sensor 245, the APC valve 244, the vacuum pump 246, the gate valves 10a to 10c, the temperature sensors 263, 620 and 720, the heaters 207, 630 and 730, the transferrer 850, and the like.

The CPU 121a is configured to be capable of reading and executing the control program from the memory 121c and reading the recipe from the memory 121c in response to an input of an operation command from the input/output device 122 or the like. The CPU 121a is configured to be capable of, according to contents of the recipe thus read, controlling the flow rate regulating operations of various substances (various gases) by the MFCs 241a to 241e, the opening/closing operations of the valves 243a to 243e, the pressure regulating operation by the APC valve 244 based on the opening/closing operation of the APC valve 244 and the pressure sensor 245, the start and stop of the vacuum pump 246, the temperature regulating operations of the heaters 207, 630 and 730 based on the temperature sensors 263, 620 and 720, the rotation and the rotation speed adjusting operations of the boat 217 by the rotator 267, the raising/lowering operation of the boat 217 by the boat elevator 115, the opening/closing operation of the shutter 219s by the shutter opening/closing mechanism 115s, the operation of the transferrer 850, and the like.

The controller 121 may be configured by installing, in the computer, the above-described program recorded and stored in the external memory 123. The external memory 123 includes, for example, a magnetic disk such as a HDD or the like, an optical disk such as a CD or the like, a semiconductor memory such as a USB memory, a SSD or the like, and so forth. The memory 121c and the external memory 123 are configured as a computer readable recording medium. Hereinafter, the memory 121c and the external memory 123 are collectively and simply referred to as a recording medium. As used herein, the term “recording medium” may refer to a case of solely including the memory 121c, a case of solely including the external memory 123, or a case of including both. The provision of the program to the computer may be performed by using a communication means such as the Internet or a dedicated line without using the external memory 123.

### (2) Substrate Processing Process

A method of processing a substrate by using the above-mentioned substrate processing apparatus 100 as a process of manufacturing a semiconductor device, that is, an example of a processing sequence for forming a film in a first region out of first and second regions of a wafer 200 as a substrate, is described. More specifically, an example of a processing sequence for forming a film in first and third regions out of first, second and third regions of a wafer 200 is described.

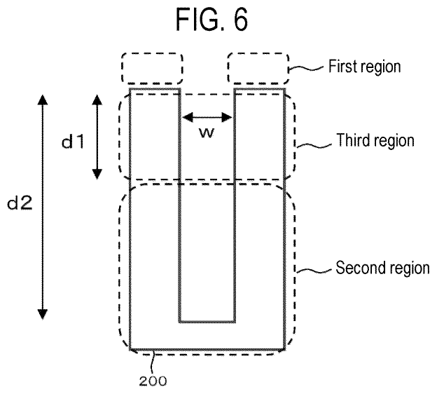

In this embodiment, an example is described in which a wafer 200 including a three-dimensional structure such as a trench, groove, or hole formed on its surface is used. Also, in this embodiment, a region that constitutes an outer surface of a recess and is adjacent to an opening of the recess is referred to as a first region. A region that constitutes an inner surface of the recess and includes a bottom surface of the recess is referred to as a second region. Of the regions that constitute the inner surface of the recess, a region that is located closer to the opening than the second region and is adjacent to the opening and the second region is referred to as a third region (see FIG. 6).

In this embodiment, steps A, B, and C described below are performed in the named order. In step A, a wafer 200 including the first region whose surface is terminated by a first termination and the second region whose surface is terminated by the first termination is prepared (preparation step). Specifically, in step A, a wafer 200 including the first, second and third regions whose surfaces are terminated by the first termination is prepared. In step B, a first processing solution containing a liquid that reacts with the first termination is supplied to the wafer 200, thereby selectively removing the first termination in the first region with respect to the first termination in the second region (removal step). Specifically, in step B, the first termination in the first region and the third region are selectively removed with respect to the first termination in the second region. In step C, a film-forming agent is supplied to the wafer 200, thereby selectively forming a film in the first region with respect to the second region (film formation step). Specifically, in step C, a film is selectively formed in the first region and the third region with respect to the second region. Step A is performed in the film-forming apparatus 500, step B is performed in the first cleaning apparatus 600, and step C is performed in in the film-forming apparatus 500, respectively. In the following description, the operation of each part constituting the substrate processing apparatus 100 is controlled by the controller 121.

In the present disclosure, the meaning of “selectively remove” and “selectively process” is not limited to the case where removal or processing is performed on one, and removal or processing is not performed on the other at all. This meaning includes the case where an amount, speed, probability, or the like of removal or processing performed on one is relatively greater than an amount, speed, probability, or the like of removal or processing performed on the other. In other words, this meaning includes the case where removal or processing is performed preferentially on one over the other. Similarly, the meaning of “selectively form” and “selectively adsorb” is not limited to the case where formation or adsorption is performed on one, and formation or adsorption is not performed on the other at all. This meaning includes the case where an amount, speed, probability, or the like of formation or adsorption performed on one is relatively greater than an amount, speed, probability, or the like of formation or adsorption performed on the other. In other words, this meaning includes the case where formation or adsorption is performed preferentially on one over the other.

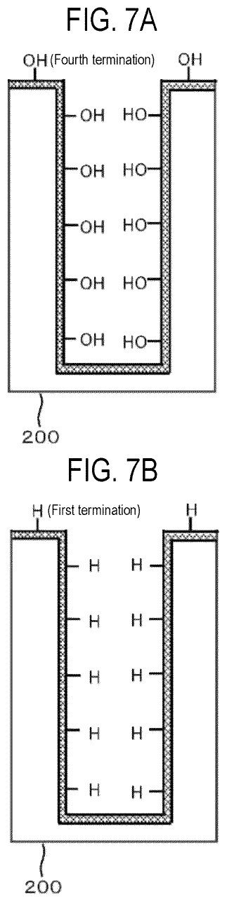

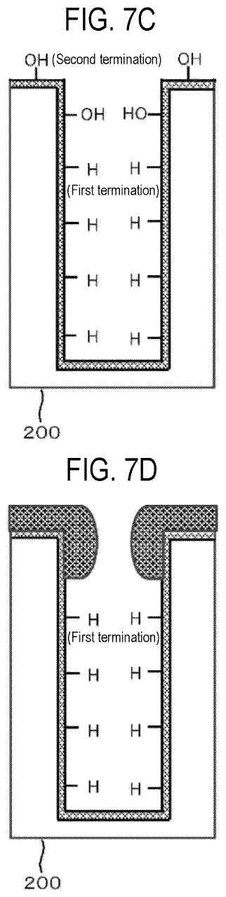

Step A in this embodiment is: (a) preparing a wafer 200 including a first region, which forms an outer surface of a recess and is adjacent to an opening of the recess and whose surface is terminated by a first termination, and a second region, which forms an inner surface of the recess and whose surface is terminated by the first termination (see FIG. 7B).

In this embodiment, there is described a case where in step A, the following are performed:
(a-0) step a0 of forming a fourth termination in the first region and the second region (see FIG. 7A); and
(a-1) step a1 of forming the first termination in the first region and the second region by supplying a first modifying agent to the wafer 200 (see FIG. 7B).

Further, in this embodiment, there is described a case where in step a0, an intermediate layer including a surface with the fourth termination formed thereon is formed in the first region and the second region by performing a cycle a predetermined number of times (n₁ times where n₁ is an integer of 1 or 2 or more) (see FIG. 7A), the cycle including:
(a-0a) step a0a of supplying a precursor to the wafer 200; and
(a-0b) step a0b of supplying an oxidizing agent as a reactant to the wafer 200.

Step B in this embodiment is:
(b) removing the first termination in the first region by supplying to the wafer 200 a first processing solution containing a liquid that reacts with the first termination so that a density of the first termination in the first region is smaller than a density of the first termination in the second region (see FIG. 7C).

Step C in this embodiment is:
(c) forming a film in the first region by supplying a film-forming agent to the wafer 200 on which step B is performed, such that a deposition rate in the first region is greater than a deposition rate in the second region (see FIG. 7D).

Further, in this embodiment, there is described a case where in step C, a film is formed in the first region by performing a cycle a predetermined number of times (n₂ times where n₂ is an integer of 1 or 2 or more), the cycle including:
step c1 of supplying a precursor to the wafer 200; and
step c2 of supplying an oxidizing agent to the wafer 200.

In the present disclosure, the above-mentioned processing sequence may be expressed as follows for the sake of convenience. Similar notations are used in the following description of modifications and other embodiments.

(precursor→oxidizing agent)×n₁→first modifying agent→first processing solution→(precursor→oxidizing agent)×n₂

The term “wafer” used herein may refer to a wafer itself or a stacked body of the wafer and a predetermined layer or film formed on a surface of the wafer. The phrase “a surface of a wafer” used herein may refer to a surface of a wafer itself or a surface of a predetermined layer or the like formed on the wafer. The expression “a predetermined layer is formed on a wafer” used herein may mean that a predetermined layer is directly formed on a surface of a wafer itself or that a predetermined layer is formed on a layer or the like formed on the wafer. The term “substrate” used herein may be synonymous with the term “wafer.”

As used herein, the term “agent” includes at least one selected from the group of a gaseous substance and a liquid substance. The liquid substance includes a mist-like substance. That is, each of the film-forming agent (precursor and oxidizing agent), the first modifying agent and the second modifying agent may include a gaseous substance, a liquid substance such as a mist-like substance or the like, or both.

As used herein, the term “layer” includes at least one selected from the group of a continuous layer and a discontinuous layer. For example, first to seventh layers and the intermediate layer may include continuous layers, discontinuous layers, or both.

In the present disclosure, the description that the film-forming agent (precursor and oxidizing agent), the first modifying agent and the second modifying agent are adsorbed on or react with the surface of the wafer 200 includes a case where they are adsorbed on or react with the surface of the wafer while remaining undecomposed, and a case where intermediates produced by decomposition of them or desorption of their ligands are adsorbed on or react with the surface of the wafer 200.

### (Wafer Charging and Boat Loading)

When a plurality of wafers 200 are charged to the boat 217 by the transferrer 850 (wafer charging), the boat 217 supporting the wafers 200 is loaded into the process chamber 201 by the boat elevator 115 as shown in FIG. 2 (boat loading).

### (Pressure Regulation and Temperature Regulation)

After the boat loading is completed, an inside of the process chamber 201, i.e., a space where the wafers 200 are present, is exhausted into vacuum (exhausted into a reduced pressure) by the vacuum pump 246 so that a desired pressure (degree of vacuum) is achieved. At this time, the APC valve 244 is feedback-controlled based on the pressure information measured by the pressure sensor 245. Further, the wafers 200 in the process chamber 201 are heated by the heater 207 so that they achieve a desired processing temperature. At this time, the state of supply of electric power to the heater 207 is feedback-controlled based on the temperature information detected by the temperature sensor 263 so that the inside of the process chamber 201 achieves a desired temperature distribution. Further, the rotation of the wafers 200 by the rotator 267 is started. In addition, the heaters 630 and 730 are controlled based on temperature information detected by the temperature sensors 620 and 720 so that temperatures of the first and second processing solutions in the process tanks 610 and 710 reach desired temperatures. The exhaust of the process chamber 201, the heating and rotation of the wafers 200, and the regulation of the temperatures of the first processing solution and the second processing solution are continued at least until the processing of the wafers 200 is completed.

Thereafter, the following steps A, B, and C are executed in sequence. In step A, the following steps a0 and a1 are executed in sequence.

### [Step A: Preparation Step]

### (Step a0)

In this step, a precursor and an oxidizing agent are supplied to the wafer 200. This forms an oxide layer (intermediate layer) in the first and second regions. In this step, specifically, the following steps a0a and a0b are executed in sequence.

[Step a0a]

In this step, the precursor is supplied to the wafer 200 in the process chamber 201. The precursor used in this step is particularly referred to as a first precursor, and a precursor supply system that supplies the first precursor to the wafer 200 is particularly referred to as a first precursor supply system (first precursor exposure system).

Specifically, the valve 243a is opened to allow the precursor to flow into the gas supply pipe 232a. A flow rate of the precursor is regulated by the MFC 241a. The precursor is supplied into the process chamber 201 via the nozzle 249a, and is exhausted from the exhaust port 231a. At this time, the precursor is supplied to the wafers 200 (precursor supply). At this time, the valves 243d and 243e may be opened to supply an inert gas into the process chamber 201 via each of the nozzles 249a and 249b.

Processing conditions when supplying the precursor in this step are exemplified as follows.
Processing temperature: room temperature to 600 degrees C, particularly 50 to 400 degrees C
Processing pressure: 1 to 101,325 Pa, particularly 1 to 1,300 Pa
Precursor supply flow rate: 0.001 to 2 slm, particularly 0.001 to 1 slm
Precursor supply time: 1 second to 240 minutes, particularly 30 seconds to 120 minutes
Inert gas supply flow rate (per gas supply pipe): 0 to 20 slm

In the present disclosure, the notation of a numerical range such as “50 to 400 degrees C” means that the lower limit and the upper limit are included in the range. Therefore, for example, “50 to 400 degrees C” means “50 degrees C or more and 400 degrees C or less.” The same applies to other numerical ranges. Further, the processing temperature in the present disclosure means the temperature of the wafers 200 or the temperature inside the process chamber 201, and the processing pressure means the pressure inside the process chamber 201, i.e., the pressure of the space where the wafers 200 exist. Moreover, a processing time means a time during which the processing is continued. In addition, when the supply flow rate includes 0 slm, the 0 slm means a case where the substance is not supplied. The same applies to the following description.

By supplying the precursor to the wafer 200 under the above-mentioned processing conditions, at least a portion of molecular structures of molecules constituting the precursor is adsorbed on the first region and the second region, more specifically, the first region, the second region and the third region, thereby making it possible to form the first layer in these regions.

As the precursor, for example, a Si-containing material containing silicon (Si) as a main element constituting the intermediate layer formed in step a0 may be used. As the Si-containing material, for example, a material containing halogen and Si, i.e., halosilane may be used. Halogen includes chlorine (Cl), fluorine (F), bromine (Br), iodine (I), and the like. As the halosilane, for example, chlorosilane, fluorosilane, bromosilane, iodosilane, and the like, may be used.

As the precursor, for example, chlorosilane such as monochlorosilane (SiH₃Cl), dichlorosilane (SiH₂Cl₂), trichlorosilane (SiHCl₃), tetrachlorosilane (SiCl₄), hexachlorodisilane (Si₂Cl₆), and octachlorotrisilane (Si₃Cl₈) may be used.

In addition to these, for example, a substance containing an amino group and Si, i.e., aminosilane, may also be used as the precursor. The amino group is a monovalent functional group obtained by removing H from ammonia, primary amine, or secondary amine, and may be expressed as —NH₂, —NHR, or —NR₂. Also, R represents an alkyl group, and the two Rs in —NR₂ may be the same or different.

As the precursor, for example, aminosilane such as tetrakis(dimethylamino)silane (Si[N(CH₃)₂]₄), tris(dimethylamino)silane, bis(diethylamino)silane (Si[N(C₂H₅)₂]₂H₂), bis(tertiary-butylamino)silane (SiH₂[NH(C₄H₉)]₂), (diisopropylamino)silane (SiH₃[N(C₃H₇)₂]), or the like may be used.

One or more of these substances may be used as the precursor.

As the inert gas, it may be possible to use a nitrogen (N₂) gas, or a rare gas such as an argon (Ar) gas, a helium (He) gas, a neon (Ne) gas, a xenon (Xe) gas or the like. One or more of these gases may be used as the inert gas. This also applies to each step described later.

After the first layer is formed in the first to third regions of the wafer 200, the valve 243a is closed to stop the supply of the precursor into the process chamber 201. Then, the inside of the process chamber 201 is vacuum-exhausted to remove gaseous substances remaining inside the process chamber 201 from the inside of the process chamber 201. At this time, the valves 243d and 243e are opened to supply an inert gas into the process chamber 201 via the nozzles 249a and 249b. The inert gas acts as a purge gas, thereby purging the space where the wafers 200 are present, i.e., the inside of the process chamber 201.

[Step a0b]

After step a0a is completed, an oxidizing agent is supplied as a reactant to the wafer 200 in the process chamber 201, that is, the wafer 200 on which the first layer is formed in the first to third regions. The oxidizing agent used in this step is particularly referred to as a first reactant or first oxidizing agent, and a reactant supply system or oxidizing agent supply system that supplies the first reactant or first oxidizing agent to the wafer 200 is particularly referred to as a first reactant supply system or first oxidizing agent supply system (first reactant exposure system or first oxidizing agent supply system).

Specifically, the valve 243b is opened to allow the oxidizing agent to flow into the gas supply pipe 232b. A flow rate of the oxidizing agent is regulated by the MFC 241b. The oxidizing agent is supplied into the process chamber 201 via the nozzle 249b and exhausted from the exhaust port 231a. At this time, the oxidizing agent is supplied to the wafer 200 (oxidizing agent supply).

Processing conditions when supplying the oxidizing agent in this step are exemplified as follows.
Oxidizing agent supply flow rate: 0.001 to 20 slm, particularly 0.001 to 10 slm
Oxidizing agent supply time: 1 second to 240 minutes, particularly 30 seconds to 120 minutes
   Other processing conditions may be the same as those used when supplying the precursor in step a0a.

By supplying the oxidizing agent to the wafer 200 under the above-mentioned processing conditions, it is possible to oxidize at least a portion of the first layer formed in the first to third regions. As a result, the first layer is oxidized in the first to third regions, and the second layer is formed in which an OH group (hydroxyl group) termination (OH termination) is formed.

As the oxidizing agent, for example, an oxygen (O)-containing substance may be used. As the O-containing substance, for example, oxygen (O₂), ozone (O₃), nitrous oxide (N₂O), nitric oxide (NO), nitrogen dioxide (NO₂), carbon monoxide (CO), carbon dioxide (CO₂), and the like may be used. As the oxidizing agent, one or more of these substances may be used.

Moreover, for example, an O- and H-containing substance may be used as the oxidizing agent. For example, water vapor (H₂O), hydrogen peroxide (H₂O₂), H₂+O₂, H₂+O₃, and the like may be used as the O- and H-containing gas. That is, an O-containing substance+H-containing substance may also be used as the O- and H-containing substance. In this case, a deuterium (D)-containing substance may also be used instead of the H-containing substance. Deuterium (D₂) may also be used as the D-containing substance. One or more of these substances may be used as the oxidizing agent.

In the present disclosure, a combined description such as “H₂+O₂” means a mixture of H₂ and O₂. When supplying a mixture, two substances may be mixed in a supply pipe and then supplied into the process chamber 201, or two substances may be separately supplied into the process chamber 201 through different supply pipes and mixed in the process chamber 201.

After the first layer formed in the first to third regions of the wafer 200 is changed to the second layer, the valve 243b is closed to stop the supply of the oxidizing agent into the process chamber 201. Then, gaseous substances and the like remaining in the process chamber 201 are removed from the inside of the process chamber 201 by the same processing procedure and processing conditions as those for the purging in step a0a.

### [Performing a Predetermined Number of Times]

A cycle of performing the above-mentioned steps a0a and a0b non-simultaneously, i.e., without synchronization, in the named order is performed n₁ times (where n₁ is an integer of 1 or 2 or more), so that it is possible to form an intermediate layer in the first and second regions, more specifically, in the first, second and third regions of the wafer 200. For example, when using the above-mentioned precursor and oxidizing agent, a SiO layer, for example, may be formed as the intermediate layer in the first to third regions. In this way, an intermediate layer including a surface with an OH termination as the fourth termination formed thereon may be formed in the first to third regions (see FIG. 7A). In other words, it is possible to form the fourth termination in the first to third regions. The fourth termination formed in the first to third regions act as adsorption sites for a first modifying agent supplied in step a1 described later. That is, the intermediate layer including the fourth termination acts as an adsorption promoting layer for the first modifying agent. The above-mentioned cycle is desirably repeated multiple times until a thickness of the intermediate layer formed by stacking the second layer reaches a desired thickness.

### (Step a1)

After step a0 is completed, a first modifying agent is supplied to the wafer 200 in the process chamber 201, i.e., the wafer 200 on which the intermediate layer is formed in the first to third regions.

Specifically, the valve 243c is opened to allow the first modifying agent to flow into the gas supply pipe 232c. A flow rate of the first modifying agent is regulated by the MFC 241c. The first modifying agent is supplied into the process chamber 201 via the nozzle 249a and exhausted from the exhaust port 231a. At this time, the first modifying agent is supplied to the wafer 200. At this time, the valves 243d and 243e may be opened to supply an inert gas into the process chamber 201 via each of the nozzles 249a and 249b.

Processing conditions when supplying the first modifying agent in this step are exemplified as follows.
Processing temperature: 25 to 500 degrees C, particularly 50 to 300 degrees C
Processing pressure: 1 to 13,300 Pa, particularly 50 to 1,330 Pa
First modifying agent supply flow rate: 0.01 to 3 slm, particularly 0.5 to 1 slm
First modifying agent supply time: 0.1 seconds to 120 minutes, particularly 30 seconds to 60 minutes
   Other processing conditions may be the same as those used when supplying the precursor in step a0a.

By supplying the first modifying agent to the wafer 200 under the above-mentioned processing conditions, at least a portion of molecular structures of molecules constituting the first modifying agent is adsorbed on the first and second regions, specifically, the first to third regions of the wafer 200 to form the third layer (adsorption suppression layer). Specifically, the fourth termination (OH termination) formed in the first to third regions are reacted with the first modifying agent, so that at least a portion of the molecular structures of the molecules constituting the first modifying agent is adsorbed on the first to third regions. This makes it possible to terminate the surfaces of the first to third regions with at least a portion of the molecular structures of the molecules constituting the first modifying agent. Examples of the at least a portion of the molecular structures of the molecules constituting the first modifying agent include a residue (e.g., Si—H) containing bonds between atoms (e.g., Si) that react with the fourth termination and hydrogen groups (H groups), and a residue (e.g., Si—OR) in which atoms that react with the fourth termination are bonded to alkoxy groups. When terminated with these residues, a H termination or alkoxy-group termination is formed as the first termination in the first to third regions (see FIG. 7B). The first termination formed in the first to third regions is a termination that imparts hydrophobicity to an outermost surface of the wafer 200, and acts as an inhibitor that inhibits adsorption of a film-forming agent to the surface of the wafer 200 in step C described below.

The first modifying agent may be, for example, a substance in which hydrogen (H) and an amino group are bonded to Si, i.e., aminosilane, such as tris(dimethylamino)silane (Si[N(CH₃)₂]₃H), bis(diethylamino)silane (Si[N(C₂H₅)₂]₂H₂), bis(tertiary-butylamino)silane (SiH₂[NH(C₄H₉)]₂), (diisopropylamino)silane (SiH₃[N(C₃H₇)₂]), (diisobutylamino)silane (SiH₃[N(C₄H₉)₂]), (diisopentylamino)silane (SiH₃[N(C₅H₁₁)₂]), or the like. In particular, it is desirable to use a substance in which three H atoms and one amino group are bonded to Si, i.e., monoaminosilane, such as (diisobutylamino)silane or (diisopropylamino)silane. By using the monoaminosilane as the first modifying agent, it is possible to form the H-termination more uniformly and sufficiently in the first to third regions in this step.

Further, the first modifying agent may be, for example, a substance in which an alkoxy group and an amino group are bonded to Si, such as (dimethylamino)trimethoxysilane (Si(OCH₃)₃[N(CH₃)₂]), (dimethylamino)triethoxysilane (Si(OC₂H₅)₃[N(CH₃)₂]), (dimethylamino)triprotoxysilane (Si(OC₃H₇)₃[N(CH₃)₂]), or (dimethylamino)tributoxysilane (Si(OC₄H₉)₃[N(CH₃)₂]). In particular, it is desirable to use a substance in which three alkoxy groups and one amino group are bonded to Si. By using such a substance as the first modifying agent, it is possible to form alkoxy-group termination more uniformly and sufficiently in the first to third regions in this step.

As the first modifying agent, one or more of these substances may be used.

After the first termination is formed in the first to third regions of the wafer 200, the valve 243c is closed to stop the supply of the first modifying agent into the process chamber 201. Then, gaseous substances and the like remaining in the process chamber 201 are removed from the inside of the process chamber 201 by the same processing procedure and processing conditions as those for the purging in step a0a.

### (After-Purge and Atmospheric Pressure Restoration)

After step a1 is completed, an inert gas as a purge gas is supplied into the process chamber 201 from each of the nozzles 249a and 249b, and is exhausted from the exhaust port 231a. As a result, the inside of the process chamber 201 is purged, and gaseous substances and the like remaining in the process chamber 201 are removed from the inside of the process chamber 201 (after-purge). Thereafter, the atmosphere inside the process chamber 201 is replaced with an inert gas, and the pressure inside the process chamber 201 is returned to the atmospheric pressure (atmospheric pressure restoration).

### (Boat Unloading and Wafer Discharging)

Thereafter, the seal cap 219 is lowered by the boat elevator 115, and the lower end of the manifold 209 is opened. The wafers 200 are then unloaded from the lower end of the manifold 209 to an outside of the reaction tube 203 while being supported by the boat 217 (boat unloading). The wafers 200 are taken out from the boat 217 by the transferrer 850 after being unloaded to the outside of the reaction tube 203 (wafer discharging).

The wafers 200 taken out from the boat 217 by the transferrer 850 are transferred through the transfer chamber 800 and placed on a mounting table (not shown) installed in the first cleaning apparatus 600.

### [Step B: Removal Step]

In this step, a first processing solution containing a liquid that reacts with the first termination is supplied to the wafer 200 in the first cleaning apparatus 600, i.e., the wafer 200 on which the first terminations are formed in the first to third regions.

Specifically, the wafer 200 is exposed to the first processing solution supplied via the processing solution supply pipe 640 and stored in the process tank 610. More specifically, the wafer 200 placed on the mounting table in the first cleaning apparatus 600 is immersed in the first processing solution stored in the process tank 610 by a mover (not shown) installed in the first cleaning apparatus 600.

Processing conditions when supplying the first processing solution in this step (i.e., when exposing to the first processing solution) are exemplified as follows.
Exposure temperature: 0 to 100 degrees C, particularly 15 to 50 degrees C
Exposure time: 0.1 seconds to 120 minutes, particularly 30 seconds to 60 minutes

In the present disclosure, the exposure temperature means a temperature of the wafer 200 in the processing solution or the temperature of the processing solution. The exposure time means a time during which the exposure continues, specifically, a time during which the processing solution is supplied. These terms hold true in the following description.

By supplying the first processing solution to the wafer 200 under the above-mentioned processing conditions, the first termination in the first region can be removed (destroyed or modified) such that a density of the first termination in the first region is smaller than a density of the first termination in the second region. Further, the first termination in the third region can be removed so that a density of the first termination in the third region is smaller than the density of the first termination in the second region. In other words, it is possible to selectively remove the first termination formed in the first region and the third region with respect to the first termination formed in the second region. Specifically, it is possible to remove the first termination formed in the first region and the third region while leaving the first termination formed in the second region. For example, when a liquid of a compound containing an OH termination in its molecule is used as the liquid that reacts with the first termination, it is possible to replace the first terminations (H terminations) in the first region and the third region with OH terminations as the second terminations (see FIG. 7C). In this case, the first terminations that inhibit adsorption of a film-forming agent supplied in step C described below are left in the second region, while the second terminations that act as adsorption sites for the film-forming agent supplied in step C are formed in the first and third regions.

The first processing solution is a liquid that reacts with the first termination, or a solution containing a liquid that reacts with the first termination and an additive that changes (increases or reduces) a surface tension of the liquid. In this embodiment, an example in which an additive that reduces the surface tension of the liquid is used is described. The additive that reduces the surface tension of the liquid that reacts with the first termination exhibits a surface tension smaller than that of the liquid that reacts with the first termination, or exhibits an effect of decreasing the surface tension of the liquid that reacts with the first termination by being mixed with the liquid that reacts with the first termination. By containing the liquid that reacts with the first termination and the additive, the first processing solution becomes a liquid with a surface tension smaller than that of the liquid that reacts with the first termination.

The liquid that reacts with the first termination may be, for example, liquids of compounds containing OH terminations in the molecules thereof, such as H₂O and H₂O₂. In particular, when the first termination contains a H termination, it is possible to effectively remove the H termination by using liquids of these compounds as the liquid that reacts with the first termination. As the liquid that reacts with the first termination, one or more of these substances may be used. In addition, by using the liquids of the compounds containing the OH terminations in the molecules thereof as the liquid that reacts with the first termination, it is possible to replace the reacted H termination (first termination) with an OH termination (second termination).

In addition, for example, a liquid containing H₂O may be used as the liquid that reacts with the first termination, and a liquid further containing H₂O₂ (which may also be called a hydrogen peroxide solution) may be used as the first processing solution. By using the liquid further containing H₂O₂ as the first processing solution, it is possible to further improve the effect of removing the first termination formed in the first region and the third region.

The additive may be, for example, a compound containing a structural formula R—COH, such as alkyl ether such as polyoxyethylene alkyl ether or the like, polyhydric alcohol ether such as alkyl glycoside or the like, fatty acid ester such as sorbitan fatty acid ester or the like, and so forth. In this regard, R may be at least one selected from the group of carbon (C), hydrogen (H), oxygen (O), nitrogen (N), and fluorine (F), or at least one selected from the group of C, H, and O.

In addition, the additive may be, for example, at least one selected from the group of a compound in which one or more H atoms of alkane represented by CₘH₍₂ₘ₊₂₎ (particularly, paraffin-based hydrocarbon) or alkene represented by CₘH₂ₘ (particularly, olefin-based hydrocarbon) are substituted with OH (which may also be called alcohol), and a compound in which one or more H atoms of aromatic hydrocarbon are substituted with OH (which may also be called phenol).

Further, the additive may include, for example, one or more compounds selected from the group including methanol, ethanol, propanol, butanol, and ethylene glycol. Also, H₂O, which may be contained as an impurity in ethanol, may act as the liquid that reacts with the first termination in the first processing solution.

In addition to the additives mentioned above, any surfactant that is able to reduce the surface tension of the liquid that reacts with the first termination may be used.

At least one selected from the group of a surface tension of the first processing solution, a supply time of the first processing solution, and a temperature of the first processing solution is desirably regulated according to at least one selected from the group of (i) a distance d1 from the opening to a position in the third region farthest from the opening (see FIG. 6), (ii) a width w of the opening (see FIG. 6), and (iii) a type of the first termination. For example, the longer the distance d1, the smaller the width w of the opening, or the greater the hydrophobicity of the first termination, the more difficult it is for the first processing solution to penetrate into the recess. Therefore, in such a case, it is desirable to regulate at least one selected from the group of a) reducing the surface tension of the first processing solution (e.g., increasing a concentration of the additive), b) lengthening the supply time of the first processing solution, and c) increasing the temperature of the first processing solution. On the other hand, for example, the shorter the distance d1, the larger the width w of the opening, or the less hydrophobicity of the first termination, the easier it is for the first processing solution to penetrate into the recess. In such a case, therefore, it is desirable to regulate at least one selected from the group of a′) increasing the surface tension of the first processing solution (specifically, decreasing the concentration of the additive in the first processing solution), b′) shortening the supply time of the first processing solution, and c′) decreasing the temperature of the first processing solution. In this way, it is desirable to regulate at least one selected from the group of the surface tension, supply time, and temperature of the first processing solution so that the first processing solution is able to penetrate into the third region.

For example, when water is used as the liquid that reacts with the first termination and ethanol is used as the additive, the concentration of the additive in the first processing solution is exemplified as 0 to 99.9%, particularly 0 to 90%. A concentration of 0% indicates that the first processing solution does not contain any additive. In addition, the concentration of the additive is exemplified as a concentration at which a contact angle of the first processing solution with respect to the first to third regions terminated with the first termination is 10 to 100°, particularly 10 to 90°.

After the first terminations in the first and third regions of the wafer 200 are selectively removed and replaced with the second terminations, the mover lifts the wafer 200 from the process tank 610 and places the wafer 200 on the mounting table in the first cleaning apparatus 600. The transferrer 850 transfers the wafer 200 placed on the mounting table out of the first cleaning apparatus 600 and charges the wafer 200 to the boat 217 via the transfer chamber 800.

### (Wafer Charging and Boat Loading)

Thereafter, using the same procedure as the wafer charging and boat loading described above, the wafers 200 are charged to the boat 217 and loaded into the process chamber 201.

### (Pressure Regulation and Temperature Regulation)

Thereafter, the pressure and temperature in the process chamber 201 are regulated using the same procedures as those for the pressure regulation and temperature regulation described above.

### [Step C: Film Formation Step]

In this step, a precursor and an oxidizing agent are supplied to the wafer 200 as film-forming agents. This selectively forms a film in the first region and the third region. Specifically, in this step, the following steps c1 and c2 are executed in sequence.

[Step c1]

After step B is completed, a precursor is supplied to the wafer 200 that is transferred from the first cleaning apparatus 600 into the process chamber 201 of the film-forming apparatus 500, i.e., the wafer 200 on which the second terminations are selectively formed in the first region and the third region. In this step, the precursor may be supplied to the wafer 200 by the same processing procedure and processing conditions as those in the precursor supply in step a0a. The precursor used in this step may be specifically referred to as a second precursor.

By supplying the precursor to the wafer 200 under the above-mentioned processing conditions, at least a portion of molecular structures of molecules constituting the precursor is selectively adsorbed on the first region and the third region where the second terminations are formed, thereby making it possible to selectively form the fourth layer in these regions. At this time, the adsorption of at least a portion of the molecular structures of the molecules constituting the precursor to the second region is suppressed by an adsorption suppression effect of the first termination formed in the second region.

In addition, the precursor (second precursor) supplied to the wafer 200 in this step may be a gas containing one or more of the gases listed as examples of the precursor (first precursor) supplied to the wafer 200 in step a0a. The second precursor may be the same as or different from the first precursor. When a precursor different from the first precursor is used as the second precursor, a second precursor supply system (second precursor exposure system) configured to supply the second precursor is further installed. The second precursor supply system is composed of, for example, a gas supply pipe connected to the nozzle 249a, an MFC, and a valve, just like the precursor supply system described above.

After the fourth layer is selectively formed in the first and third regions of the wafer 200, the valve 243a is closed to stop the supply of the precursor into the process chamber 201. Then, gaseous substances and the like remaining in the process chamber 201 are removed from the inside of the process chamber 201 by the same processing procedure and processing conditions as those for the purging in step a0a.

[Step c2]

After step c1 is completed, an oxidizing agent is supplied as a reactant to the wafer 200 in the process chamber 201, i.e., the wafer 200 on which the fourth layer is selectively formed in the first and third regions. In this step, the oxidizing agent may be supplied to the wafer 200 by the same processing procedure and processing conditions as those in the oxidizing agent supply in step a0b. The oxidizing agent used in this step may be specifically referred to as a second reactant or a second oxidizing agent.

By supplying the oxidizing agent to the wafer 200 under the above-mentioned processing conditions, it is possible to oxidize at least a portion of the fourth layer formed in the first region and the third region in step c1. As a result, the fourth layer is oxidized in the first region and the third region, and the fifth layer constituted by OH terminations formed on the surface thereof is formed.

In addition, the oxidizing agent (second oxidizing agent) supplied to the wafer 200 in this step may be a gas containing one or more of the gases given as examples of the oxidizing agent (first oxidizing agent) supplied to the wafer 200 in step a0b. The second oxidizing agent may be the same as or different from the first oxidizing agent. When an oxidizing agent different from the first oxidizing agent is used as the second oxidizing agent, a second oxidizing agent supply system (second oxidizing agent exposure system) configured to supply the second oxidizing agent is further installed. The second oxidizing agent supply system is composed of, for example, a gas supply pipe connected to the nozzle 249b, an MFC, and a valve, just like the above-mentioned oxidizing agent supply system.

After the fourth layer formed in the first and third regions of the wafer 200 is changed to the fifth layer, the valve 243b is closed to stop the supply of the oxidizing agent into the process chamber 201. Then, gaseous substances and the like remaining in the process chamber 201 are removed from the inside of the process chamber 201 by the same processing procedure and processing conditions as those for the purging in step a0a.

### [Performing a Predetermined Number of Times]

A cycle of performing the above steps c1 and c2 non-simultaneously in the named order is performed n₂ times (where n₂ is an integer of 1 or 2 or more) to form a film in the first region such that a deposition rate in the first region is higher than a deposition rate in the second region. Further, it is possible to form a film in the third region such that a deposition rate in the third region is higher than the deposition rate in the second region. In other words, it is possible to selectively form a film in the first region and the third region of the wafer 200 (see FIG. 7D). In detail, it is possible to selectively form a film in the first region and the third region, which are the regions near the opening of the recess, while suppressing film formation in the second region, which is the region inside the recess. The above cycle is desirably repeated multiple times until a thickness of a film formed by stacking the fifth layer reaches a desired film thickness. In addition, it is desirable to form an air gap in the recess by repeating the above cycle multiple times until the film formed in the first region and the third region closes the opening of the recess.

After step C is completed, after-purge, atmospheric pressure restoration, boat unloading, and wafer discharging are performed in sequence. The details are the same as those performed after step A.

### (3) Effects of the Embodiment

According to this embodiment, one or more of the following effects may be obtained.

(a) In step B, the first termination of the first region is removed such that the density of the first termination in the first region is less than the density of the first termination in the second region, thereby allowing free film formation in these regions. For example, in step C, which is performed after steps A and B, it is possible to selectively form a film in the first region with respect to the second region.

(b) In step B, the first termination of the third region is removed such that the density of the first termination in the third region is less than the density of the first termination in the second region, thereby allowing free film formation in these regions. For example, in step C, which is performed after steps A and B, it is possible to selectively form a film in the third region with respect to the second region.

(c) The first processing solution contains the additive that changes (e.g., reduces) the surface tension of the liquid that reacts with the first termination. This makes it easier for the first processing solution to penetrate into the recess. Further, by regulating an amount of the additive in the first processing solution, it is possible for the first processing solution to freely penetrate into a desired region (deep region or shallow region) inside the recess. This allows free film formation in the first to third regions.

(d) In step B, at least one selected from the group of the surface tension of the first processing solution, the supply time of the first processing solution, and the temperature of the first processing solution is regulated according to at least one selected from the group of (i) the distance d1 from the opening to a position in the third region farthest from the opening (see FIG. 6), (ii) the width w of the opening (see FIG. 6), and (iii) the type of the first termination. This makes it possible to accurately remove the first termination in the predetermined first and third regions while leaving the first termination in the predetermined second region. That is, since it is possible to precisely remove the first termination in the desired first and third regions, it is possible to improve precision of the regions (i.e., the first and third regions) in which the film is selectively formed in step C. In other words, these regulations make it possible to control (determine) a boundary position between the region (i.e., the second region) where the first termination is removed and the region (i.e., the third region) where the first termination is left.

(e) In step C, by supplying the film-forming agent to the wafer 200 after step B, the film is formed in the first region such that the deposition rate in the first region is higher than the deposition rate in the second region. This makes it possible to selectively form a film in the first region with respect to the second region.

(f) In step C, by supplying the film-forming agent to the wafer 200 after step B, the film is formed in the third region such that the deposition rate in the third region is higher than the deposition rate in the second region. This makes it possible to selectively form a film in the third region with respect to the second region.

(g) The first termination inhibits the adsorption of the film-forming agent to the outermost surface of the wafer 200, so that in step C, it is possible to more selectively form the film in the first region and the third region.

(h) Since the first terminations are terminations that impart hydrophobicity to the outermost surface of the wafer 200, in step B, it is possible to reliably make the density of the first termination in the first region (specifically, the first and third regions) smaller than the density of the first termination in the second region. This is described below.

When the first terminations, which are terminations that impart hydrophobicity to the outermost surface of the wafer 200, i.e., hydrophobic terminations, are formed on an inner bottom side of the recess (second region), it becomes difficult for the first processing solution to penetrate into the second region. This becomes more noticeable when the first terminations, which are hydrophobic terminations, are formed near the opening of the recess (in the first region or third region). Therefore, in step B, it becomes difficult for the first processing solution to penetrate into the second region, which makes it possible to selectively remove the first termination in the first and third regions. As a result, it is possible to reliably make the density of the first termination in the first and third regions smaller than the density of the first termination in the second region.

### (4) Modifications

The substrate processing sequence in this embodiment may be modified as shown in the following modifications. These modifications may be combined arbitrarily.

### (Modification 1)

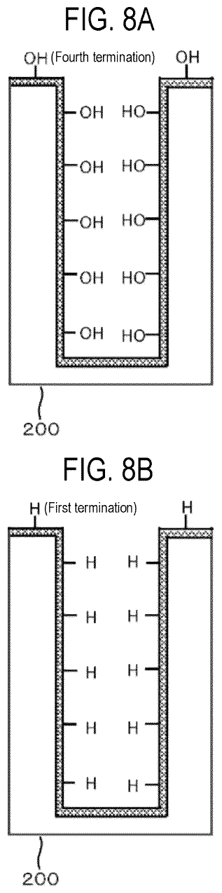

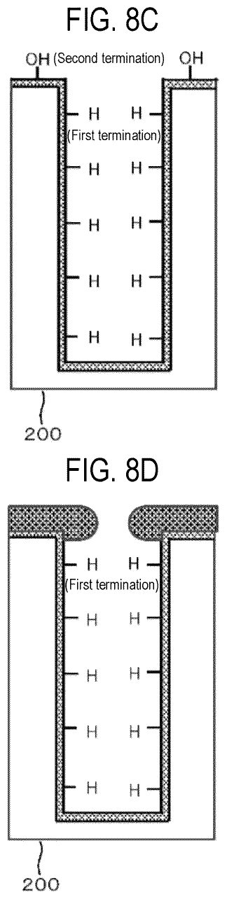

In the above-described embodiment, there is described the example in which the first terminations formed in the first region and the third region are removed in step B. However, the present disclosure is not limited thereto. For example, in step B, the first termination formed solely in the first region may be removed (see FIG. 8C).

In this modification, the same effects as those of the above-described embodiment may be obtained. Further, according to this modification, in step C, deposition on the inner surface of the recess is inhibited, and a deposited film on an upper surface of the recess is formed so as to protrude toward the opening of the recess (see FIG. 8D), which is particularly effective when it is desired to form a large air gap.

### (Modification 2)

In the above-described embodiment, there is described the example in which the film-forming agent is supplied to the wafer 200 after step B is performed. However, the present disclosure is not limited to such an embodiment. For example, an etching agent may be supplied to the wafer 200 after step B is performed. In this modification, the same effects as those of the above-described embodiment may be obtained. In other words, a selective etching process may be performed in the first region.

### (Modification 3)

In the above-described embodiment, there is described the example in which the precursor and the oxidizing agent are supplied as film-forming agents in step C. However, the present disclosure is not limited thereto. For example, a catalyst may also be supplied as a film-forming agent in step C.

In this modification, the same effects as those of the above-described embodiment may be obtained. Further, in this modification, since it is possible to perform the film-forming process at a low temperature, it is possible to suppress the first termination from being detached from the second region during the execution of step C. This makes it possible to more selectively form a film in the first region (the first region and the third region) in step C.

### Second Embodiment of the Present Disclosure

Next, the second embodiment of the present disclosure is described. The differences from the first embodiment described above are mainly described, and other points are not described.

### (1) Substrate Processing Process

In this embodiment, a method of processing a substrate using the above-mentioned substrate processing apparatus 100 as a process of manufacturing a semiconductor device, that is, an example of a processing sequence for forming a film in the second region out of the first and second regions of a wafer 200, is described. More specifically, an example of a processing sequence for forming a film in the second region out of the first, second and third regions of a wafer 200 is described.

In the processing sequence according to this embodiment, after steps A and B described in the above embodiment are performed in the named order, the following steps are performed:
(d) step D (modification step) of forming a third termination in the first region by supplying a second modifying agent to the wafer 200 on which step B is performed;
(e) step E (removal step) of removing the first termination in the second region by supplying a second processing solution, containing a liquid that reacts with the first termination and having a surface tension that is smaller than the surface tension of the first processing solution, to the wafer 200 on which step D is performed; and
(f) step F (film formation step) of forming a film in the second region by supplying a film-forming agent to the wafer 200 on which step D is performed, such that a deposition rate in the second region is higher than a deposition rate in the first and third regions.

Further, in this embodiment, there is described a case where in step F, a film is formed in the second region by performing a cycle a predetermined number of times (n3 times where n3 is an integer of 1 or 2 or more), the cycle including:
step f1 of supplying a precursor to the wafer 200; and
step f2 of supplying an oxidizing agent as a reactant to the wafer 200.

Steps D and F are performed in the film-forming apparatus 500, and step E is performed in the second cleaning apparatus 700.

For the sake of convenience, the above-mentioned processing sequence may also be denoted as follows.

(precursor→oxidizing agent)×n₁→first modifying agent→first processing solution→second modifying agent→second processing solution→(precursor→oxidizing agent)×n₃

After steps A and B are performed, wafer charging, boat loading, pressure regulation, and temperature regulation are performed, and then the following steps D, E, and F are sequentially performed. The wafer charging, the boat loading, the pressure regulation, the temperature regulation, and steps A and B in this embodiment may be performed in the same manner as those in the first embodiment described above, and therefore descriptions thereof are omitted.

### [Step D: Modifying Step]

After step B is completed, a second modifying agent is supplied to the wafer 200 that is transferred from the first cleaning apparatus 600 into the process chamber 201 of the film-forming apparatus 500, i.e., the wafer 200 on which the second terminations are selectively formed in the first and third regions.

Specifically, the valve 243c is opened to allow the second modifying agent to flow into the gas supply pipe 232c. A flow rate of the second modifying agent is regulated by the MFC 241c. The second modifying agent is supplied into the process chamber 201 through the nozzle 249a and exhausted from the exhaust port 231a. At this time, the second modifying agent is supplied to the wafer 200 (second modifying agent supply). At this time, the valves 243d and 243e may be opened to supply an inert gas into the process chamber 201 through each of the nozzles 249a and 249b.

Processing conditions when supplying the second modifying agent in this step are exemplified as follows.
Processing temperature: room temperature (25 degrees C) to 500 degrees C, particularly room temperature to 250 degrees C
Processing pressure: 5 to 2,000 Pa, particularly 10 to 1,000 Pa
Second modifying agent supply flow rate: 1 to 3 slm, particularly 1 to 0.5 slm
Second modifying agent supply time: 1 second to 120 minutes, particularly 30 seconds to 60 minutes
Inert gas supply flow rate (per gas supply pipe): 0 to 20 slm

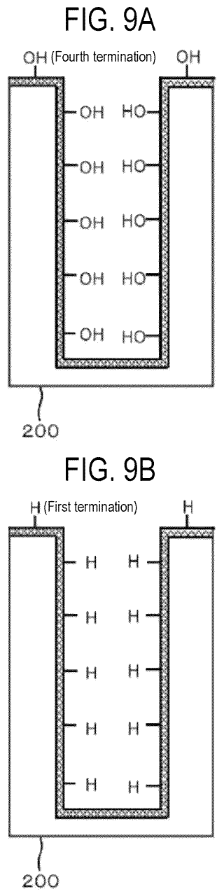

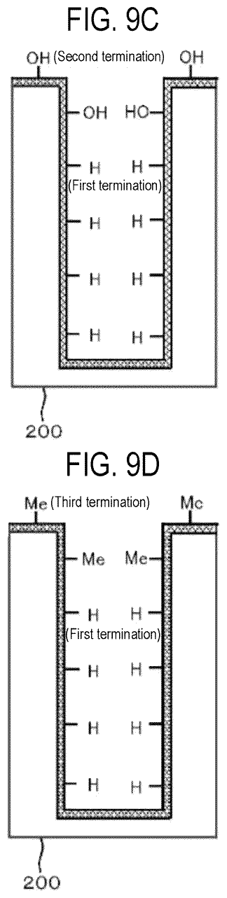

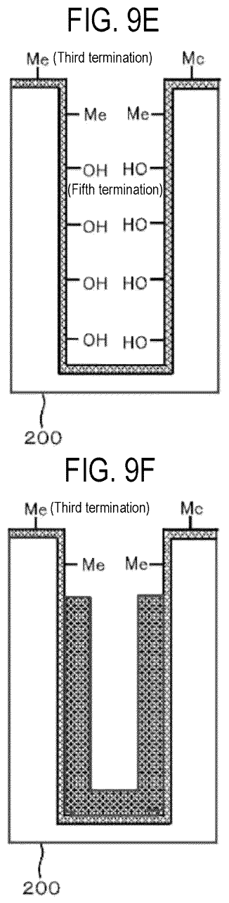

By supplying the second modifying agent to the wafer 200 under the above-mentioned processing conditions, at least a portion of molecular structures of molecules constituting the second modifying agent is selectively adsorbed on the first region (specifically, the first region and the third region), thereby making it possible to selectively form the sixth layer (adsorption suppression layer) in the first region and the third region. Specifically, while suppressing adsorption of at least a portion of the molecular structures of the molecules constituting the second modifying agent to the second region, it is possible to react the second terminations formed in the first region and the third region with the second modifying agent, thus selectively adsorbing at least a portion of the molecular structures of the molecules constituting the second modifying agent on the first region and the third region. As a result, it is possible to terminate the surfaces of the first region and the third region with at least a portion of the molecular structures of the molecules constituting the second modifying agent. The at least a portion of the molecular structures of the molecules constituting the second modifying agent may be, for example, a residue containing a bond between an atom (e.g., Si) that reacts with the second termination and an alkyl group (e.g., a methyl group (Me group), an ethyl group (Et group), or a tert-butyl group (tert-Bu group)). More specifically, such a residue may be, for example, a trimethylsilyl group (Si-Me₃), a triethylsilyl group (Si-Et₃), a tert-butyldimethylsilyl group (Si—(CH₃)₂C(CH₃)₃), and the like. In this case, Si constituting these silyl groups contained in the second modifying agent bonds with O of the second terminations (OH terminations, or OH groups) in the first and third regions, and alkyl group terminations as third terminations are formed in the first and third regions (see FIG. 9D). In this case, it is possible to form the third terminations that inhibit adsorption of a film-forming agent supplied in step F in the first and third regions, while the first terminations that inhibit adsorption of the film-forming agent supplied in step F described below are left in the second region.

The first termination formed in the second region and the third termination formed in the first and third regions are both terminations (hydrophobic terminations) that impart hydrophobicity (i.e., water repellency) to the outermost surface of the wafer 200. Further, comparing the first terminations such as H terminations with the third terminations such as alkyl group terminations, the third terminations are more hydrophobic than the first terminations. Therefore, the first and third regions in which the third terminations are formed are more hydrophobic (i.e., less hydrophilic) than the second region in which the first terminations are formed.

In addition, the first terminations react with the second processing solution supplied to the wafer 200 in step E, which is described later, and are thereby removed from the second region. On the other hand, the third terminations are less likely to react with the second processing solution and are less likely to be removed from the first and third regions than the first terminations. That is, the first terminations react more easily with the second processing solution and are more likely to be selectively removed than the third terminations.

The second modifying agent may be, for example, a substance in which an amino group and an alkyl group are bonded to Si, i.e., alkylaminosilane, such as (dimethylamino)trimethylsilane ((CH₃)₂NSi(CH₃)₃), (diethylamino)triethylsilane ((C₂H₅)₂NSi(C₂H₅)₃), (dimethylamino)triethylsilane ((CH₃)₂NSi(C₂H₅)₃), (diethylamino)trimethylsilane ((C₂H₅)₂NSi(CH₃)₃), (diisopropylamino)trimethylsilane ((C₃H₇)₂NSi(CH₃)₃), or the like. In particular, the second modifying agent may desirably be a substance in which three alkyl groups and one amino group are bonded to Si, i.e., trialkylaminosilane, such as (dimethylamino)trimethylsilane, (diethylamino)triethylsilane, or the like. As the second modifying agent, one or more of these substances may be used.

After selectively forming the third terminations in the first region and the third region of the wafer 200, the valve 243c is closed to stop the supply of the second modifying agent into the process chamber 201. Then, gaseous substances and the like remaining in the process chamber 201 are removed from the inside of the process chamber 201 by the same processing procedure and processing conditions as those for the purging in step a0a of the first embodiment described above.

After step D is completed, after-purge, atmospheric pressure restoration, boat unloading, and wafer discharging are performed sequentially. The details are the same as those performed after step A.

The wafer 200 taken out from the boat 217 by the transferrer 850 is transferred through the transfer chamber 800 and placed on a mounting table (not shown) installed in the second cleaning apparatus 700.

### [Step E: Removal Step]

In this step, the second processing solution, containing a liquid that reacts with the first termination and having a surface tension that is smaller than the first processing solution, is supplied to the wafer 200 in the second cleaning apparatus 700, i.e., the wafer 200 on which the third terminations are formed in the first and third regions and the first terminations are formed in the second region.

Specifically, the wafer 200 is exposed to the second processing solution supplied via the processing solution supply pipe 740 and stored in the process tank 710. More specifically, the wafer 200 placed on the mounting table in the second cleaning apparatus 700 is immersed in the second processing solution stored in the process tank 710 by a mover (not shown) provided in the second cleaning apparatus 700.

Processing conditions when supplying the second processing solution in this step (i.e., exposing the wafer to the second processing solution) are exemplified as follows.
Exposure temperature: 0 to 100 degrees C, particularly 15 to 50°degrees C
Exposure time: 1 second to 120 minutes, particularly 30 seconds to 60 minutes

By supplying the second processing solution to the wafer 200 under the above-mentioned processing conditions, it is possible to remove (destroy or modify) the first termination in the second region so that a density of the first termination in the second region is smaller than a density of the third termination in the first region (specifically, the first region and the third region). In other words, it is possible to selectively remove the first termination formed in the second region with respect to the third termination formed in the first region and the third region. Specifically, it is possible to remove the first termination formed in the second region while leaving the third termination formed in the first region and the third region. For example, when a liquid of a compound containing an OH termination in its molecule is used as the liquid that reacts with the first termination, it is possible to replace the first termination (H termination) in the second region with an OH termination as the fifth termination (see FIG. 9E). In this case, it is possible to form the fifth termination (OH termination) that act as an adsorption site for the film-forming agent supplied in step F in the second region, while the third termination that inhibits adsorption of the film-forming agent supplied in step F described later is left in the first region and the third region.

The second processing solution is a solution containing a liquid that reacts with the first termination and an additive that changes the surface tension of the liquid. In this embodiment, an example in which an additive for reducing the surface tension of the liquid is used is described. The additive for reducing the surface tension of the liquid that reacts with the first termination, and the liquid that reacts with the first termination may be the same as or different from those described in the first embodiment.

At least one selected from the group of a surface tension of the second processing solution, a supply time of the second processing solution, and a temperature of the second processing solution is desirably regulated according to at least one selected from the group of (i) a distance d2 from the opening to a bottom of the recess (see FIG. 6), (ii) the width w of the opening (see FIG. 6), (iii) the type of the first termination and (iv) a type of the third termination. For example, the longer the distance d2, the smaller the width w of the opening, or the greater the hydrophobicity of the first termination or the third termination, the more difficult it becomes for the second processing solution to penetrate into the recess. In particular, this tendency becomes more pronounced when the hydrophobicity of the third termination in the first and third regions, which are regions near the opening of the recess, is greater than the hydrophobicity of the first termination in the second region, which is the region near the bottom of the recess. Therefore, in such cases, it is desirable to regulate at least one selected from the group of a) reducing the surface tension of the second processing solution (for example, increasing a concentration of the additive), b) lengthening the supply time of the second processing solution, and c) increasing the temperature of the second processing solution. In this way, it is desirable to regulate at least one selected from the group of the surface tension, supply time, and temperature of the second processing solution, so that the second processing solution is able to penetrate into the second region, and more desirably so that the second processing solution is able to penetrate into the bottom of the recess in the second region. In addition, it is desirable that the supply time of the second processing solution in this step is longer than the supply time of the first processing solution in step B, and the temperature of the second processing solution in this step is higher than the temperature of the first processing solution in step B.

For example, when water is used as the liquid that reacts with the first termination and ethanol is used as the additive, the concentration of the additive in the second processing solution is exemplified as 0.1 to 99.9%, particularly 10 to 90%. In addition, the concentration of the additive is exemplified as a concentration at which a contact angle of the second processing solution with respect to the second region whose surface is terminated by the first termination, and a contact angle of the second processing solution with respect to the first and third regions whose surfaces are terminated by the third termination are both 10 to 100°, particularly 10 to 90°. The concentration of the additive in the second processing solution in this step is desirably higher than the concentration of the additive in the first processing solution in step B.

After the first termination in the second region of the wafer 200 is selectively removed and replaced with the fifth termination, the mover lifts the wafer 200 from the process tank 710 and places the wafer 200 on the mounting table in the second cleaning apparatus 700. The transferrer 850 transfers the wafer 200 placed on the mounting table out of the second cleaning apparatus 700 and charges the wafer 200 to the boat 217 via the transfer chamber 800.

### (Wafer Charging and Boat Loading)

Thereafter, the wafers 200 are charged to the boat 217 and transferred into the process chamber 201 using the same procedure as the wafer charging and boat loading in the first embodiment described above.

### (Pressure Regulation and Temperature Regulation)

Thereafter, the pressure and temperature in the process chamber 201 are regulated using the same procedures as those for the pressure regulation and temperature regulation in the first embodiment described above.

### [Step F: Film Formation Step]

In this step, a precursor and an oxidizing agent are supplied to the wafer 200 as film-forming agents. This selectively forms a film in the second region. Specifically, in this step, the following steps f1 and f2 are executed in sequence.

[Step f1]

After step E is completed, a precursor is supplied to the wafer 200 that is transferred from the second cleaning apparatus 700 into the process chamber 201 of the film-forming apparatus 500, i.e., the wafer 200 on which the fifth termination is selectively formed in the second region. In this step, the precursor may be supplied to the wafer 200 by the same processing procedure and processing conditions as those in the precursor supply in step a0a of the first embodiment described above. The precursor used in this step may be referred to as a third precursor.

By supplying the precursor to the wafer 200 under the above-mentioned processing conditions, at least a portion of molecular structures of molecules constituting the precursor is selectively adsorbed on the second region where the fifth termination is formed, thereby making it possible to selectively form the sixth layer in the second region. At this time, adsorption of at least a portion of the molecular structures of the molecules constituting the precursor to the first and third regions is suppressed by an adsorption suppression effect of the third termination formed in these regions (see FIG. 9F).

In addition, the precursor (third precursor) supplied to the wafer 200 in this step may be a gas containing one or more of the gases given as examples of the precursor (first precursor) supplied to the wafer 200 in step a0a of the first embodiment. The third precursor may be the same as or different from the first precursor. When a precursor different from the first precursor is used as the third precursor, a third precursor supply system (third precursor exposure system) configured to supply the third precursor is further installed. The third precursor supply system is composed of, for example, a gas supply pipe connected to the nozzle 249a, an MFC, and a valve, just like the precursor supply system described above.

After the sixth layer is selectively formed in the second region of the wafer 200, the valve 243a is closed to stop the supply of the precursor into the process chamber 201. Then, gaseous substances and the like remaining in the process chamber 201 are removed from the inside of the process chamber 201 by the same processing procedure and processing conditions as those for the purging in step a0a described in the first embodiment.

[Step f2]

After step f1 is completed, an oxidizing agent is supplied as a reactant to the wafer 200 in the process chamber 201, i.e., the wafer 200 on which the sixth layer is selectively formed in the second region. In this step, the oxidizing agent may be supplied to the wafer 200 by the same processing procedure and processing conditions as those in the oxidizing agent supply in step a0b described in the first embodiment. The oxidizing agent used in this step may be referred to as a third reactant or a third oxidizing agent.

By supplying the oxidizing agent to the wafer 200 under the above-mentioned processing conditions, it is possible to oxidize at least a portion of the sixth layer formed in the second region in step f1. As a result, a seventh layer obtained by oxidizing the sixth layer and constituted by forming OH terminations on the surface thereof is formed in the second region.

In addition, the oxidizing agent (third oxidizing agent) supplied to the wafer 200 in this step may be a gas containing one or more of the gases given as examples of the oxidizing agent (first oxidizing agent) supplied to the wafer 200 in step a0b described in the first embodiment. The third oxidizing agent may be the same as or different from the first oxidizing agent. When an oxidizing agent different from the first oxidizing agent is used as the third oxidizing agent, a third oxidizing agent supply system (third oxidizing agent exposure system) configured to supply the third oxidizing agent is further installed. The third oxidizing agent supply system is composed of, for example, a gas supply pipe connected to the nozzle 249b, an MFC, and a valve, just like the above-mentioned oxidizing agent supply system.

After the sixth layer formed in the second region of the wafer 200 is changed to the seventh layer, the valve 243b is closed to stop the supply of the oxidizing agent into the process chamber 201. Then, gaseous substances and the like remaining in the process chamber 201 are removed from the inside of the process chamber 201 by the same processing procedure and processing conditions as those for the purging in step a0a described in the first embodiment.

### [Performing a Predetermined Number of Times]

A cycle of performing the above steps f1 and f2 non-simultaneously in the named order is performed n₃ times (where n₃ is an integer of 1 or 2 or more) to form a film in the second region such that a deposition rate in the second region is higher than a deposition rate in the first region. Further, it is possible to form a film in the second region such that the deposition rate in the second region is higher than a deposition rate in the third region. In other words, it is possible to selectively form a film in the second region of the wafer 200 (see FIG. 9F). In detail, it is possible to selectively form a film in the second region, which is the region inside the recess, while suppressing film formation in the first region and the third region, which are the regions near the opening of the recess. The above cycle is desirably repeated multiple times until a film thickness of a film formed by stacking the seventh layer reaches a desired film thickness.

After step F is completed, after-purge, atmospheric pressure restoration, boat unloading, and wafer discharging are performed in sequence. The details are the same as those performed after step A.

### (3) Effects of the Embodiment

According to this embodiment, one or more of the following effects may be obtained.

(a) In step B, the first termination of the first region is removed so that the density of the first termination in the first region is less than the density of the first termination in the second region, thereby allowing free film formation in these regions. For example, in step F, which is performed after steps A and B, it is possible to selectively form a film in the second region with respect to the first region.

(b) In step B, the first termination in the third region is removed so that the density of the first termination in the third region is less than the density of the first termination in the second region, thereby allowing free film formation in these regions. For example, in step F, which is performed after steps A and B, it is possible to selectively form a film in the second region with respect to the third region.

(c) In step D, the third termination is formed in the first region by supplying the second modifying agent to the wafer 200 after step B. As a result, it is possible to more selectively form a film in the second region than in the first region.

(d) In step E, the first termination in the second region is removed by supplying the second processing solution, containing the liquid that reacts with the first termination and having a surface tension that is smaller than that of the first processing solution, to the wafer 200 after step D. In this manner, the second processing solution is able to penetrate into the second region (near the bottom of the recess) by using the second processing solution with a surface tension smaller than that of the first processing solution. In addition, in this embodiment, the first termination is more likely to react with the second processing solution than the third termination. Therefore, it is possible to reliably remove the first termination in the second region. By removing the first termination that inhibits the adsorption of the film-forming agent, it is possible to selectively form a film in the second region in step F.

When the first termination in the second region is a hydrophobic termination, it is difficult to cause the second processing solution to penetrate into the second region. This tendency is more pronounced when the third termination in the first region is a hydrophobic termination, and is even more pronounced when the hydrophobicity of the third termination in the first region is greater than the hydrophobicity of the first termination in the second region. In this embodiment, an example in which the hydrophobicity of the third termination (e.g., alkyl termination) in the first region (specifically, the first region and the third region) is greater than the hydrophobicity of the first termination (e.g., H termination) in the second region is used. In such a case, it is particularly effective to use the second processing solution with a smaller surface tension than the first processing solution as a means for causing the second processing solution to penetrate into the second region.

(e) In step F, by supplying the film-forming agent to the wafer 200 on which step D is performed, the film is formed in the second region such that the deposition rate in the second region is greater than the deposition rate in the first region. As a result, it is possible to selectively form the film in the second region with respect to the first region, thereby improving, for example, filling characteristics in the recess (e.g., for example, suppressing the occurrence of voids or seams).

### (3) Modifications

The substrate processing sequence according to this embodiment may be modified as shown in the following modifications. These modifications may be combined arbitrarily.

### (Modification 1)

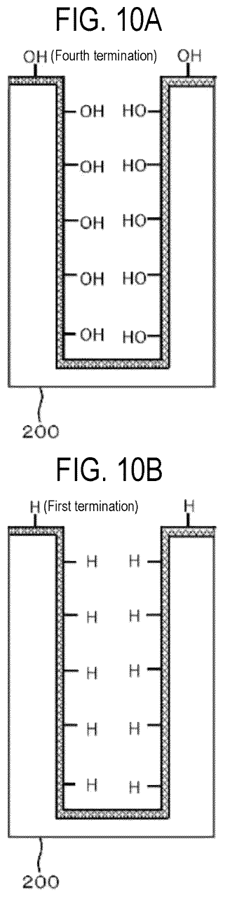

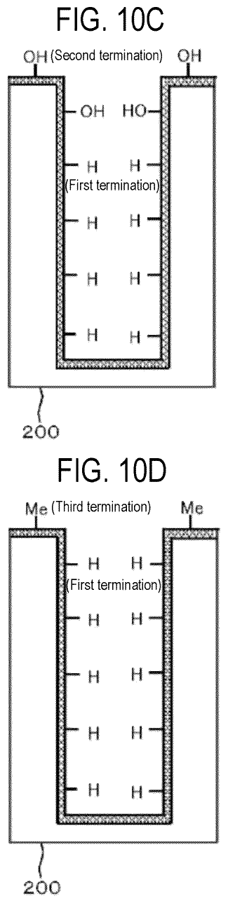

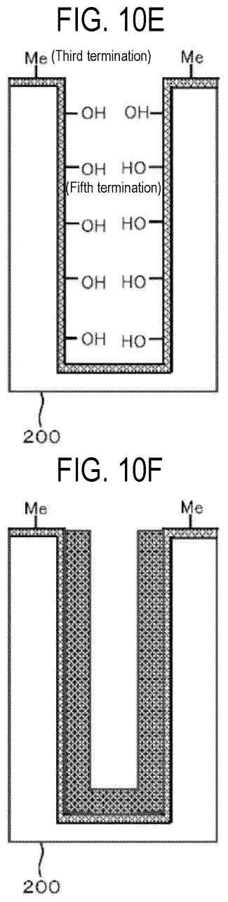

In the above-described embodiment, there is described the example in which the third terminations are formed in the first region and the third region in step D. However, the present disclosure is not limited thereto. For example, in step D, the third termination may be formed solely in the first region (see FIG. 10D).

In this modification, the same effects as those of the above-described embodiment may be obtained. Further, according to this modification, in step F, film formation on the upper surface of the recess is inhibited, thereby making it possible to selectively perform film formation solely on the entire inner surface of the recess (see FIG. 10F), which may further improve, for example, the filling characteristics.

### (Modification 2)

In the above-described embodiment, there is described the example in which step E is performed before step F. However, the present disclosure is not limited to such an embodiment. For example, after step D is performed, step F may be performed without performing step E.

In this modification, at least some of the effects of the above-described embodiment may be obtained. During the execution of step F, the first termination in the second region is more likely to be desorbed from the wafer 200 than the third termination in the first region. Therefore, even if step E is omitted, it is possible to selectively form a film in the second region by selective breakage. Further, the third termination possesses a greater effect of inhibiting the adsorption of the film-forming agent than the first termination. Therefore, even if step E is omitted, it is possible to selectively form a film in the second region. However, in order to enhance the selectivity of the film formation, it is desirable to perform step E.

### (Modification 3)

In the above-described embodiment, there is described the example in which the film-forming agent is supplied to the wafer 200 after step E. However, the present disclosure is not limited to such an embodiment. For example, an etching agent may be supplied to the wafer 200 after step E. According to this modification, the same effects as those of the above-described embodiment may be obtained. In other words, a selective etching process may be performed in the second region.

### (Modification 4)

In the above-described embodiment, there is described the example in which the third termination formed in the first and third regions, and the first termination formed in the second region are terminations that impart hydrophobicity to the outermost surface of the wafer 200. However, the present disclosure is not limited to such an embodiment. For example, at least one selected from the group of the first termination and the third termination may be a termination that imparts hydrophobicity to the outermost surface of the wafer 200. In this modification, the same effects as those of the above-described embodiment may be obtained.

### Other Embodiments of the Present Disclosure

The embodiments of the present disclosure are specifically described above. However, the present disclosure is not limited to the above-described embodiments, and various changes may be made without departing from the gist thereof.

For example, in the above-described embodiments, the first processing solution contains the additive that reduces the surface tension of the liquid. However, the present disclosure is not limited to such embodiments. For example, the first processing solution may contain an additive that increases the surface tension of the liquid depending on the liquid used. In this embodiment, the same effects as those of the above-described embodiments may be obtained.

For example, in the above-described embodiments, there is described the example in which the predetermined element contained in the precursor is Si. However, the present disclosure is not limited to such embodiments. For example, the predetermined element may also be a metal element such as titanium (Ti), zirconium (Zr), hafnium (Hf), tantalum (Ta), niobium (Nb), aluminum (Al), molybdenum (Mo), tungsten (W), germanium (Ge) or the like. In these cases, a metal-based oxide film such as a titanium oxide film (TiO film), a zirconium oxide film (ZrO film), a hafnium oxide film (HfO film), a tantalum oxide film (TaO film), a niobium oxide film (NbO film), an aluminum oxide film (AlO film), a molybdenum oxide film (MoO film), a tungsten oxide film (WO film), a germanium oxide film (GeO film) or the like is formed. The predetermined elements contained in the first and second precursors may be different from each other, and the predetermined elements contained in the first and third precursors may be different from each other. In this embodiment as well, the same effects as those of the above-described embodiments may be obtained.

For example, in the above-described embodiments, there is described the case where the oxide film is formed on the surface of the wafer 200 in the film formation step (steps C and F). However, the present disclosure is not limited to such embodiments. The film selectively formed on the surface of the wafer 200 may be any film that is able to be formed on the surface of the wafer 200 after step B, and may be, for example, a nitride film or a film of Si or a metal element alone. For example, when a nitride film is formed as the film selectively formed on the surface of the wafer 200, a nitriding agent (e.g., a nitrogen-containing gas such as an NH₃ gas or the like) may be used instead of the oxidizing agent as the reactant (second reactant and third reactant) used in the film formation step. In this embodiment, the same effects as those of the above-described embodiments may be obtained.

In the above-described embodiments, there is described the example in which a film is formed using a batch-type substrate processing apparatus 100 that processes a plurality of substrates at a time. The present disclosure is not limited to the above-described embodiments, but may also be suitably applied to, for example, a case where a film is formed using a single-substrate type substrate processing apparatus 100 that processes one or several substrates at a time. Further, in the above-described embodiments, there is described the example in which a film is formed using the substrate processing apparatus 100 including a hot wall type process furnace. The present disclosure is not limited to the above-described embodiments, but may be suitably applied to a case where a film is formed using a substrate processing apparatus 100 including a cold wall type process furnace.

Even when using these substrate processing apparatuses 100, each process may be performed under the same processing procedures and processing conditions as in the above-described embodiments and modifications, and the same effects as in the above-described embodiments and modifications may be obtained.

The above-described embodiments and modifications may be used in combination as appropriate. The processing procedures and processing conditions at this time may be the same as, for example, the processing procedures and processing conditions of the above-described embodiments and modifications.

According to the present disclosure in some embodiments, it is possible to perform a selective processing on a desired region on a surface of a recess formed in a substrate.

While certain embodiments are described, these embodiments are presented by way of example, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) preparing the substrate including a first region, which forms an outer surface of a recess and is adjacent to an opening of the recess and whose surface is terminated by a first termination, and a second region, which forms an inner surface of the recess and whose surface is terminated by the first termination; and
(b) removing the first termination in the first region by exposing the substrate to a first processing solution containing a liquid that reacts with the first termination, so that a density of the first termination in the first region is smaller than a density of the first termination in the second region.

2. The method of claim 1, wherein the inner surface of the recess of the substrate prepared in (a) further includes a third region located closer to the opening than the second region and whose surface is terminated by the first termination, and
wherein in (b), the first termination in the third region is removed so that a density of the first termination in the third region is smaller than the density of the first termination in the second region.

3. The method of claim 1, wherein the first processing solution contains an additive that changes a surface tension of the liquid.

4. The method of claim 2, wherein at least one selected from the group of a surface tension of the first processing solution, an exposure time to the first processing solution, and a temperature of the first processing solution is regulated according to at least one selected from the group of (i) a distance from the opening to a position in the third region farthest from the opening, (ii) a width of the opening, and (iii) a type of the first termination.

5. The method of claim 2, wherein the third region is adjacent to the opening.

6. The method of claim 1, wherein in (b), the first termination removed is replaced with a second termination different from the first termination.

7. The method of claim 1, further comprising:
(c) forming a film in the first region by supplying a film-forming agent to the substrate on which (b) is performed, such that a deposition rate in the first region is greater than a deposition rate in the second region.

8. The method of claim 1, further comprising:
(d) forming a third termination in the first region by supplying a second modifying agent to the substrate on which (b) is performed.

9. The method of claim 8, further comprising:
(e) removing the first termination in the second region by exposing the substrate on which (d) is performed to a second processing solution containing a liquid that reacts with the first termination and having a surface tension smaller than a surface tension of the first processing solution.

10. The method of claim 8, further comprising:
(f) forming a film in the second region by supplying a film-forming agent to the substrate on which (d) is performed, such that a deposition rate in the second region is greater than a deposition rate in the first region.

11. The method of claim 7, wherein the first termination inhibits adsorption of the film-forming agent to an outermost surface of the substrate.

12. The method of claim 10, wherein the first termination and the third termination inhibit adsorption of the film-forming agent to an outermost surface of the substrate, and
wherein an effect of inhibiting the adsorption of the film-forming agent to the outermost surface of the substrate with the third termination is greater than that with the first termination.

13. The method of claim 1, wherein the first termination is a termination that imparts hydrophobicity to an outermost surface of the substrate.

14. The method of claim 1, wherein the liquid is a liquid of a compound containing OH termination in a molecule of the compound.

15. The method of claim 1, wherein the liquid that reacts with the first termination is a liquid containing at least one selected from the group of H₂O and H₂O₂.

16. The method of claim 1, wherein (a) further includes:
(a-1) forming the first termination in the first region and the second region by supplying a first modifying agent to the substrate.

17. A method of manufacturing a semiconductor device comprising the method of claim 1.

18. A non-transitory computer-readable recording medium storing a program that causes, by a computer, a substrate processing apparatus to perform:
(a) providing a substrate including a first region, which forms an outer surface of a recess and is adjacent to an opening of the recess and whose surface is terminated by a first termination, and a second region, which forms an inner surface of the recess and whose surface is terminated by the first termination; and
(b) removing the first termination in the first region by exposing the substrate to a first processing solution containing a liquid that reacts with the first termination, so that a density of the first termination in the first region is smaller than a density of the first termination in the second region.

19. A substrate processing apparatus, comprising:
a first processing solution exposure system configured to expose a substrate to a first processing solution; and
a controller configured to be capable of controlling the first processing solution exposure system so as to perform a process of exposing the substrate including a first region, which forms an outer surface of a recess and is adjacent to an opening of the recess and whose surface is terminated by a first termination, and a second region, which forms an inner surface of the recess and whose surface is terminated by the first termination, to the first processing solution containing a liquid that reacts with the first termination, to thereby remove the first termination in the first region, so that a density of the first termination in the first region is smaller than a density of the first termination in the second region.

20. The substrate processing apparatus of claim 19, further comprising:
a first modifying agent supply system configured to supply a first modifying agent to the substrate,
wherein the controller is configured to be capable of controlling the first modifying agent supply system to perform a process of forming the first termination in the first region and the second region by supplying the first modifying agent to the substrate.
